(19) United States
(12) Patent Application Publication
(10) Pub. No.: US 2009/0032085 A1
(43) Pub. Date: Feb. 5, 2009

(54) APPARATUS FOR GENERATING AC ELECTRIC POWER FROM PHOTOVOLTAIC CELLS

(76) Inventor: Mihai Grumazescu, Winnipeg (CA)

Correspondence Address: ADE & COMPANY INC., 2157 Henderson Highway, WINNIPEG, MB, R2G1P9, CA

(21) Appl. No.: 12/103,409

(22) Filed: Apr. 15, 2008

Related U.S. Application Data
(63) Continuation-in-part of application No. 11/570,693, filed on Dec. 15, 2006.
(60) Provisional application No. 60/580,354, filed on Jun. 18, 2004.

(51) Int. Cl. H01L 31/05

(52) U.S. Cl. 136/246

(57) ABSTRACT

A light distribution system is used in a method for converting solar or artificial light into AC electricity by collecting, concentrating and time-sharing light to a number of photovoltaic cells. The cells are arranged in an array arranged such that the beam traverses relative to the photovoltaic cells so as to fall repeatedly on each of the cells as the drive arrangement causes movement of a light deflecting member. The cells are arranged in pairs connected to a primary winding of a transformer by a resonant circuit for delivering from the transformer the AC power supply substantially in a sinusoidal waveform. The movement can be in a single direction or reciprocating. The transformer can be connected to a power grid and the movement synchronized to the frequency and phase of the grid by an optical or radio link.

This application is a continuation in part of application Ser. No. 11/570,693 filed Dec. 15, 2006 which is a National Phase Application from PCT/CA05/00944 filed Jun. 6, 2005 and which claims the benefit under 35 U.S.C. 119 of Provisional Application 60/580,354 filed Jun. 18, 2004.

This invention relates to an apparatus for generating an AC electric power supply using photovoltaic conversion of concentrated light.

### BACKGROUND OF THE INVENTION

In most cases, solar energy is turned into electricity by deploying photovoltaic (PV) modules tracking or not tracking the sun. The more collecting surface built, the more electric power obtained. Solar modules have up to 25 years warranty and PV systems may be designed to be maintenance-free for several years. Sunlight is free and PV conversion is a mature technology and a marvelous zero-emission source of energy. Despite all these, in the last years, a new concern discouraged investors, final users and even governments to support PV conversion: global warming.

### SUMMARY OF THE INVENTION

It is an object of the present invention to provide the possibility of generating AC, according to the connection pattern of the PV cells, cutting costs by the elimination of the conventional inverters when AC loads are a must.

According to the invention there is provided an apparatus comprising:

a receiver of light from a source;

a plurality of photovoltaic cells each for receiving light from the receiver;

the photovoltaic cells being arranged in an array;

the receiver being arranged to direct the light in a beam along an axis;

a light redirecting member arranged on the axis and arranged to redirect the light in the beam away from the axis;

and a drive arrangement for causing a movement of the light redirecting member around the axis,

the array being arranged such that the beam traverses relative to the photovoltaic cells of the array so as to fall on a first one of the cells and to move from the first one of the cells to fall on a second one of the cells and subsequently to return to fall on the first one of the cells so as to fall repeatedly on each of the first and second cells as the drive arrangement causes said movement of the member;

wherein the first and second photovoltaic cells are connected to a primary winding of a transformer for delivering from the transformer the AC power supply substantially in a sinusoidal waveform.

Preferably a frequency of the AC power supply is controlled by controlling the rate of the movement of the light redirecting member.

Preferably the light redirecting member is arranged to direct the light into a radial plane of the axis.

Preferably the movement of the light redirecting member is continuous in one direction around the axis. However the movement may also reciprocate back and forth around the axis.

Preferably the cells and the transformer are arranged such that the movement of the beam on the cells together with the supply of the output of the cells to the transformer acts to generate a true sinusoidal waveform.

Preferably there is a plurality of pairs of cells in the array with the movement arranged so as to cause the beam to fall repeatedly on each of the first and second cells of each pair as the drive arrangement causes said movement of the member.

According to a second aspect of the invention there is provided an apparatus for generating an AC electric power supply comprising:

a receiver of light from a source;

a pair of photovoltaic cells each for receiving light from the receiver;

a light redirecting member arranged to redirect the light in the beam;

and a drive arrangement for causing a movement of the light redirecting member;

the cells and the light redirecting member being arranged such that the beam reciprocates back and forth relative to the pair of photovoltaic cells so as to fall on a first cell and to move in a first direction from the first cell to fall on a second cell and subsequently to move in a second opposite direction to return from the second cell to fall on the first cell;

wherein the first and second photovoltaic cells are connected to a primary winding of a transformer for delivering from the transformer the AC power supply substantially in a sinusoidal waveform.

Preferably there are only two cells and the beam is reciprocated back and forth between the two cells. There may however be more than two cells.

Preferably the light is directed along an axis and the light redirecting member reciprocates about the axis. However other direction of movement and positioning of the beam are possible.

Preferably a frequency of the AC power supply is controlled by controlling the rate of the movement of the light redirecting member.

Preferably the cells and the transformer are arranged such that the movement of the beam on the cells together with the supply of the output of the cells to the transformer acts to generate a true sinusoidal waveform.

Preferably the cells and the transformer are connected in a circuit with a capacitor such that the inductance and the capacitance of the circuit are selected relative to a frequency of the movement such that the circuit is resonant at the frequency.

Preferably the transformer is controlled so as to generate a required output voltage in the AC power supply while accommodating changes in light intensity in the beam.

For this purpose, the transformer may comprise a magnetic amplifier which includes a DC biasing coil between the primary coil and the output secondary coil.

Preferably the transformer is controlled by a voltage regulator which includes switch systems for adding and subtracting pairs of cells as light intensity decreases and increases.

Preferably the transformer is connected to a grid transformer to connect the AC power supply to an electricity grid and wherein there is provided a link for synchronizing the frequency and phase of the grid to the frequency and phase of the drive arrangement where the link may include a radio connection or an optical fiber.

According to a third aspect of the invention there is provided an apparatus for generating an AC electric power supply comprising:

a receiver of light from a source;

a plurality of photovoltaic cells each for receiving light from the receiver;

a light redirecting member arranged to redirect the light in the beam;

and a drive arrangement for causing a movement of the light redirecting member;

the cells and the light redirecting member being arranged such that the beam scans over the photovoltaic cells so as to fall repeatedly on each cell and to move from that cell to another cell;

wherein at least two of the cells are connected to a primary winding of a transformer for delivering from the transformer the AC power supply substantially in a sinusoidal waveform;

and wherein the cells and the transformer are connected in a circuit with a capacitor such that the inductance and the capacitance of the circuit are selected relative to a frequency of the movement such that the circuit is resonant at the frequency.

According to a fourth aspect of the invention there is provided an apparatus for generating an AC electric power supply comprising:

a receiver of light from a source;

a plurality of photovoltaic cells each for receiving light from the receiver;

a light redirecting member arranged to redirect the light in the beam;

and a drive arrangement for causing a movement of the light redirecting member;

the cells and the light redirecting member being arranged such that the beam scans over the photovoltaic cells so as to fall repeatedly on each cell and to move from that cell to another cell;

wherein at least two of the cells are connected to a primary winding of a transformer for delivering from the transformer the AC power supply substantially in a sinusoidal waveform;

wherein the transformer is connected to a grid transformer to connect the AC power supply to an electricity grid and wherein there is provided a link for synchronizing the frequency and phase of the grid to the frequency and phase of the drive arrangement.

### BRIEF DESCRIPTION OF THE DRAWINGS

One embodiment of the invention will now be described in conjunction with the accompanying drawings in which:

FIG. 1 is a 2-D longitudinal section of a first preferred embodiment.

FIG. 2 is a 3-D partial longitudinal section of the first preferred embodiment of FIG. 1.

FIG. 3 shows three versions of optical path and distribution of light inside the apparatus.

FIG. 4 is an isometric view of a second preferred embodiment defined by a single modular apparatus on a tracking platform.

FIG. 5 is an isometric view of a third preferred embodiment defined by a multiple modular apparatus on the same tracking platform;

FIG. 6 is a 3-D partial longitudinal section of the third preferred embodiment.

FIG. 7 is a schematic diagram of a device for burnout protection for use in the embodiments shown above.

FIG. 8 is a schematic diagram of a device for safety sensor fixture for use in the embodiments shown above.

FIGS. 9A, 9B and 9C are schematic diagrams of the connection patterns of the PV cells for AC and DC generation.

FIG. 10 is a schematic illustration of a preferred embodiment which uses laser transmission and distant PV generation.

FIG. 11 is a schematic plan view of an arrangement similar to that shown in FIG. 9A above including six PV cells arranged in a hexagonal arrangement around the axis and connected to a transformer for generating AC supply.

FIG. 12 is an isometric view of the arrangement of FIG. 11.

FIG. 13 is a schematic illustration of a further embodiment using a pair only of cells where the light redirecting member is reciprocated back and forth between the cells and the output of the cells is connected to a transformer for AC power supply.

FIG. 14 is a block diagram of the system of FIG. 13 showing the connection of the power supply to an electricity power grid.

In the drawings like characters of reference indicate corresponding parts in the different figures.

### DETAILED DESCRIPTION

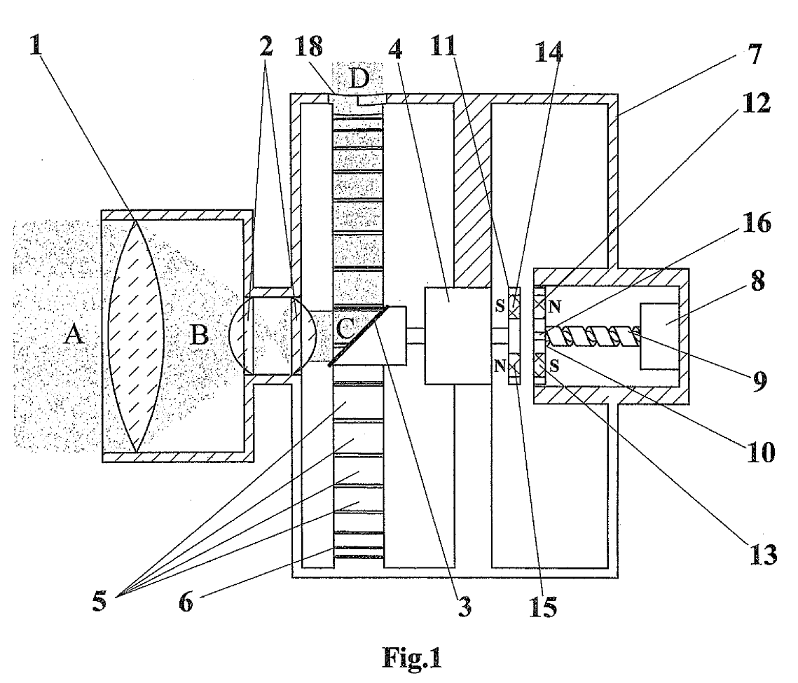

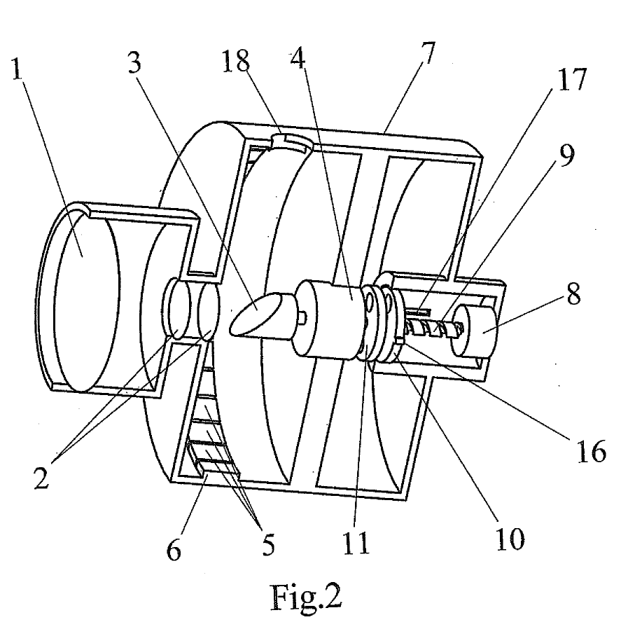

The preferred embodiment of the present invention is illustrated in FIG. 1 and FIG. 2. A lens 1 is concentrating the incoming light A in a convergent beam B which is further transformed by an optical collimator 2 in a parallel-ray beam C striking sequentially a number of PV cells 5 with its footprint of intense light D after being reflected by a fast spinning mirror 3.

The lens 1 is either a classic bi-convex one or a cheaper planar Fresnel lens, while the optical collimator comprises two identical plan-convex lenses. The spinning mirror 3 is made of a cylinder cut by a 45 degrees angled plane in respect to its axis of revolution and is driven by the high-speed electric motor 4. By spinning with over 10,000 rpm, mirror 3 is distributing in time-sharing the intense beam of light C to a large number of PV cells 5 embedded in an annular support 6 surrounding the axis of the mirror. The annular support 6 is mounted in an enclosure 7 and for an optimum operation, the enclosure 7 has to be under vacuum in order to be dust-free and to completely eliminate the drag induced by the air friction to the spinning mirror 3.

In this way, the motor 4 is operating with no back-torque and has a very low power consumption. Cheaper brush motors can also be used because sparks are rare in vacuum at low voltage and the motor's life is longer than in air operation. However, very low power brushless electric motors are preferred.

As the light intensity at the footprint D is arranged by the lens system to be magnified by a factor which can be over 400 times and consequently very hot, the main concern for safety is regarding a possible burnout of the PV cells if the mirror 3 is not spinning. If the motor 4 fails to start or stops during operation due to the driver circuit or its own failure, then one very effective and simple way to avoid burnout is to be sure that footprint D is always resting in the same point angularly around the axis at which is located a safety window 18. One simple way to implement a positional memory to the mirror in order to insure that is to add to its driving motor 4 a magnetic brake. Thus an electric motor 8 having a threaded shaft 9 drives linearly a nut-disc 10 back and forth in a longitudinal direction of the axis of the motor 4 in front of an axially aligned disc 11 fastened on the shaft of the motor 4. Both discs 10 and 11 carry two small cylindrical magnets each, 12, 13 and 14, 15 respectively. The magnets are magnetized in the direction of their thickness with the polarization shown in FIG. 1. The disc 10 is guided in longitudinal movement and prevented from rotation by two protrusions 16 sliding in cutouts 17 of the housing 7.

Each time the apparatus is turned off or during its operation one of the above mentioned failures takes place, a logic circuit takes the decision of cutting off power to the motor 4 and to starting the motor 8 for bringing the disc 10 close to the disc 11. The magnetic forces act to stop the shaft of the motor 4 precisely in the aligned position of the attracting magnets. In this way, the footprint D will rest exactly in its reset position corresponding to the safety window 18. Preferably, the motor 8 has a built-in transducer coupled to a simple counter for insuring a number of revolutions related to the pitch of its threaded shaft. So, the movement of the disc 10 will never exceed two preset positions. This magnetic brake has the advantage of being contact-less, accurate and reliable but other actuators, brakes or clutches can be envisaged by those skilled in the art, including electro-magnetic, pneumatic and hydraulic.

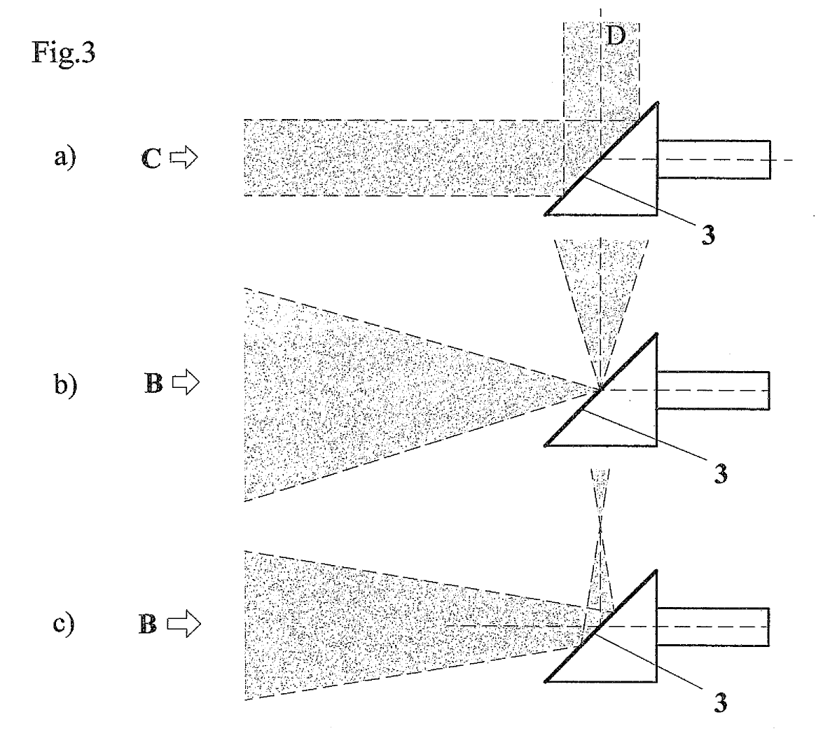

In FIGS. 3A, 3B and 3C there are illustrated three alternative versions of the optical path inside the apparatus.

FIG. 3A corresponds to the situation of using the optical collimator presented in FIG. 1 and FIG. 2, so the input beam for the mirror 3 as indicated at C is characterized by a constant cross section. This cross section will be reproduced in the footprint D, regardless of the radius of the support 6 i.e. the distance to the PV cells. This means that the number of PV cells can be changed as long as it is dictated only by the radius of the support 6. Furthermore, it means that the output electric power given by the number of PV cells is a function of the radius of the support 6 starting from the same optical arrangement, collecting surface and light intensification factor.

If the designer wishes to simplify the optics involved in the apparatus, then the optical collimator can be omitted, letting the convergent beam B strike directly the mirror 3. FIG. 3B presents the case in which the position of focus of the lens 1 falls on the mirror 3 and FIG. 3C envisages the possibility of advancing the position of the focus behind the mirror. In both cases, the radius of the support 6 has to be calculated in order to match the footprint D with the active area of the PV cells. Setting the focus of the lens 1 directly on the mirror 3 is less practical. It is necessary to avoid the overheating of the mirror 3, which is the most critical part of the apparatus, because it has to comply with several initial mechanical, optical and thermal conditions linked to each other and evolving during operation. Placing the focus of the beam on the mirror thus can lead to heating in a localized position with the potential of damage.

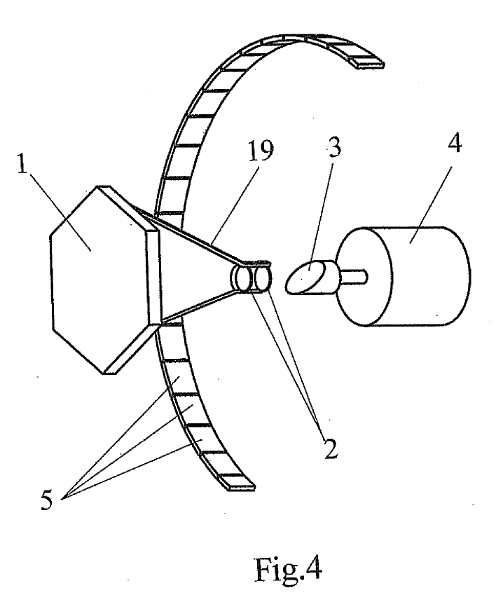

In FIG. 4 there is shown schematically a second preferred embodiment of the apparatus in which the Fresnel lens 1 is embedded in a hexagonal frame attached to a tapered enclosure 19 which houses also the optical collimator 2. This assembly thus forms a structural module representing part of or the entire outdoor exterior segment of the apparatus. The spinning mirror 3, the motor 4 and the PV cells 5 are the indoor or interior segment which can also be modular. These elements can thus be constructed and mounted separately. An important feature of this embodiment is the fact that the distance between the two segments is variable but their accurate axial alignment is a must.

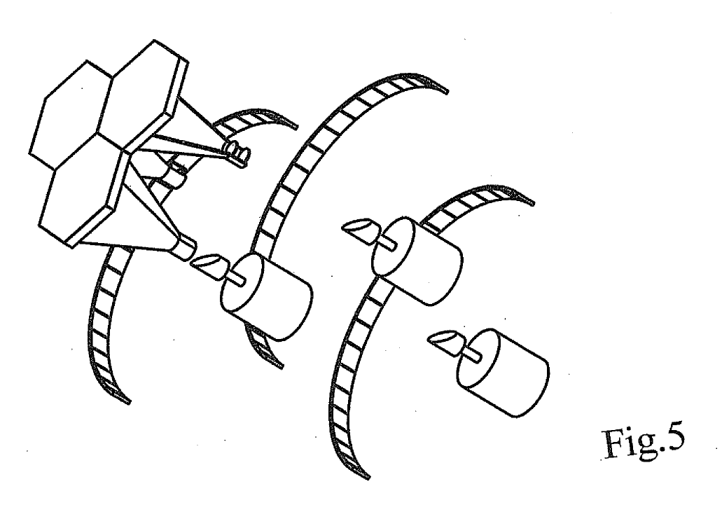

This feature is further used in FIG. 5 where a multiple PV generator is presented. The collector is a larger frame including several co-planar lenses each formed by a separate one of the exterior modules fastened in a honeycomb pattern while the interior modules are located in different parallel planes and preserving the axial optical alignment. This way, the beams of light of the different PV generators can intersect each other at right angle but are never interfering or shading each other.

A dual-axis tracking platform to support the single or multiple generators can be provided but, for convenience of illustration, is not shown in FIG. 4 and FIG. 5.

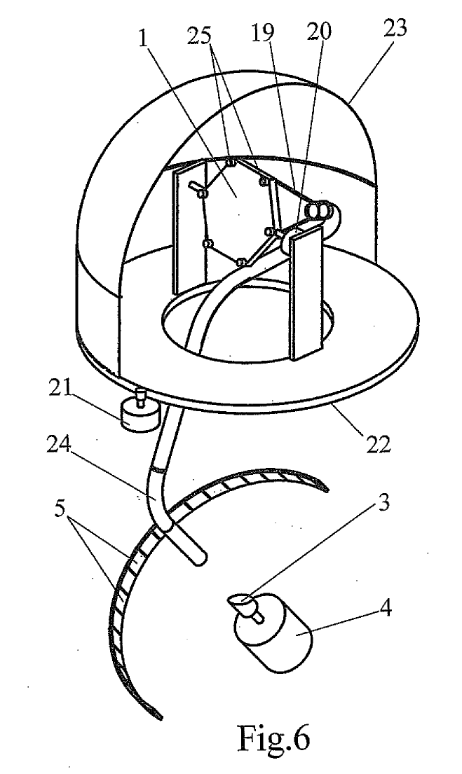

A third preferred embodiment of the present invention is illustrated in FIG. 6. The distance between the exterior and the interior modules is significantly increased by linking them through a flexible optical cable 24 which also enables the mounting of the interior module in a fixed position independent of the movement of the exterior module. The tracking platform includes a tilt motor 20 and an azimuth motor 21 together with a platform 22 supporting the lens 1 and the housing 19 which can also include optionally the optical collimator. The whole tracking platform is protected by a dome 23 made of a transparent, shock-resistant material coated with an anti-reflection layer. Light collected by the lens 1 is concentrated on the head of the flexible optical cable 24 and transported to the interior module where the spinning mirror 3 distributes the light to the PV cells 5. This is the best solution for a safe operation of the apparatus throughout the year in the most adverse environments. If the dome enclosure is under vacuum, the optics and the tracking mechanism will be even more protected against the outdoor temperature.

The dome shape is arranged to avoid retaining snow and water droplets, which is another advantage in order to reduce cleaning operations.

If desired, the dome can be cleaned remotely performed by an automated arm-tool carrying high-pressure water and washing agents. Even if the dome is scratched or cracked and has to be replaced, its price is considerably smaller than that of a PV module. But the most important is the fact that its low profile decreases tremendously the probability of being hit by a projectile of any kind, compared with a solar panel exposing a huge area to this threat. That is particularly advantageous for military and space applications.

The necessity for moving parts in the arrangement described above can be overcome by the many high quality and reliable components available on the market, and well known to one skilled in the art.

A further advantage of the concept illustrated by FIG. 6 is the flexibility of bringing the PV generator as close as possible to the load. This feature is highly appreciated by designers because the voltage drop is proportional to total wire length, this way cutting costs, increasing safety and diminishing power loss.

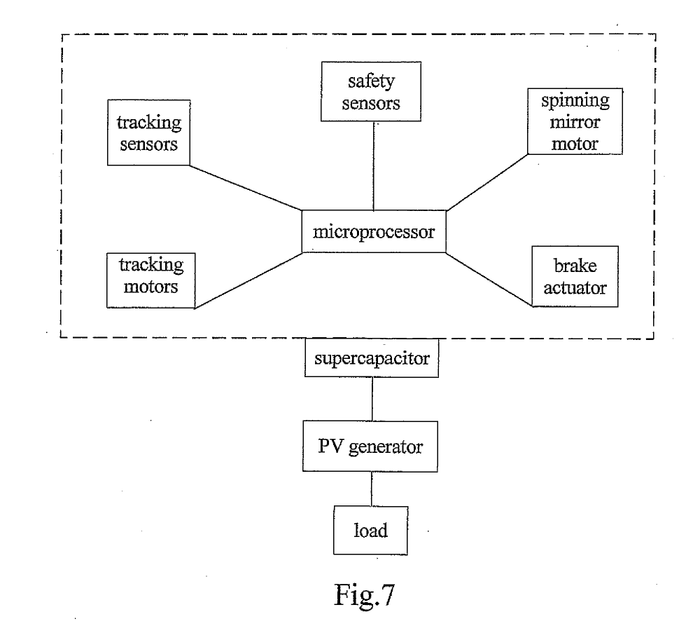

In FIG. 7 is shown the sequence of steps and presents the logic blocks and the structural elements involved in preventing the burnout of the apparatus. All decisions are taken by a microprocessor controlling the start-up, turn-off and alarms sequences as well as performing sun tracking, PV generation and load monitoring.

The start-up sequence begins with retracting the brake disc 10, starting the spinning mirror motor and continues with interrogation of tracking and safety sensors. If everything is OK, tracking motors are receiving the proper commands and after targeting the sun, PV generation begins.

At start-up or during operation, if safety sensors detect the spinning mirror is not moving or is slowing-down, then an alarm sequence is generated and the spinning motor is cut-off, the brake disc 10 is advanced and the tracking motors are actuated misaligning the collector from the sun by going to a reset position.

Turning-off sequence begins with the misaligning from the sun and going to the reset position, cutting-off the spinning mirror motor and advancing the disc brake 10.

The elements of FIG. 7 inside the dash line are powered by a super-capacitor charged during normal operation by the PV generator. This is increasing the flexibility of system design because a battery is no longer mandatory. At the same time, the life of the system is improved because a super-capacitor has a much longer life than a battery and is able to be fully discharged until start-up or safety sequence is accomplished.

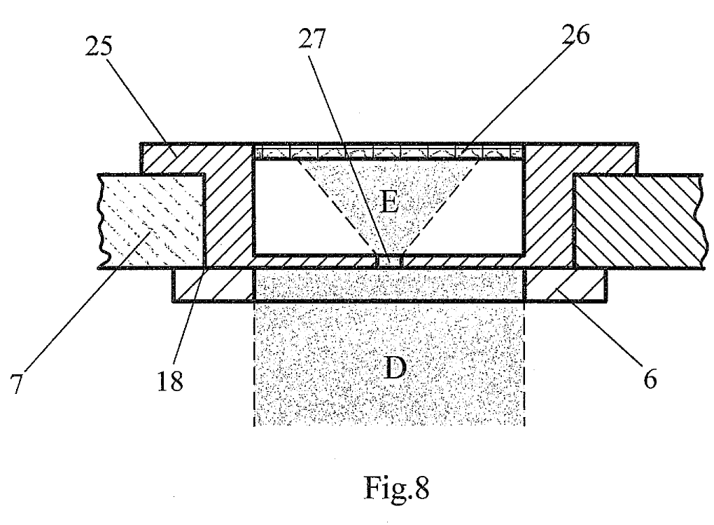

FIG. 8 shows the structure of the safety window 18. A safety optical sensor 26 is embedded in a ceramic cover 25 which reacts to a very small portion of the intense beam D passing through a tiny hole 27 and diffused in a large cone E. This structure protects the safety sensor itself against overheating or burning if the beam D is resting too long on the window 18. The cover 25 is sealed to maintain the vacuum in the enclosure 7.

The safety sensor 26 sends to the microprocessor a continuous signal if the spinning mirror is not moving or a pulsed signal after starting it. The frequency of the pulsed signal provides information on the mirror speed which is used for controlling it. This frequency will be also the frequency of the output current of the PV generator if the AC option is taken into consideration. The microprocessor can be used as a PLL (Phase Locked Loop) for controlling the frequency and phase of the AC output by suitable programming.

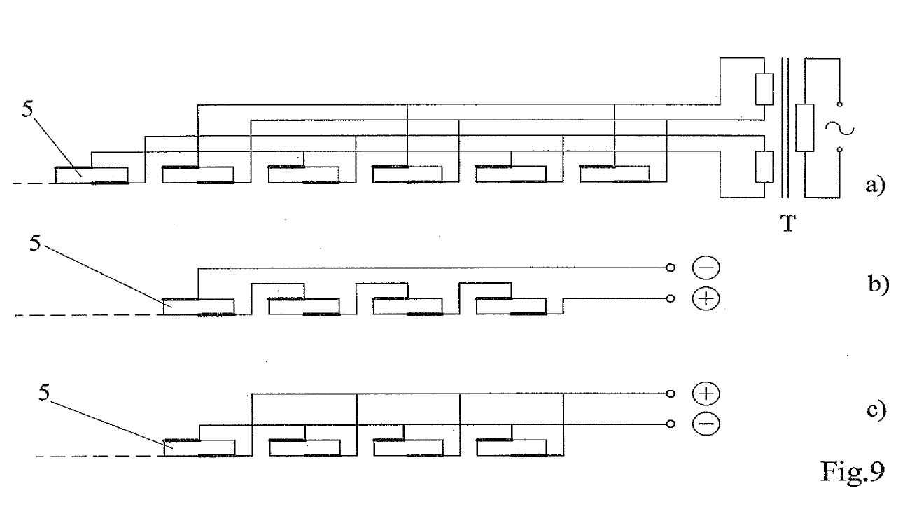

FIGS. 9A, 9B and 9C show three alternative connection patterns of the PV cells.

For single-phase AC generation shown in FIG. 9A, a transformer T is necessary for bringing the output voltage to the desired value and for insuring a true-sinusoidal waveform. Its two primary identical windings are connected to the odd and even numbered PV cells in parallel, respectively. The speed of the spinning mirror and the magnetic material of the transformer's core are adjusted to the desired frequency of the output AC which is not limited to 50 or 60 Hz.

For DC generation shown in FIGS. 9B and 9C, series and parallel connection of the PV cells are possible, according to the desired output voltage and current. The PV cells mounted on the support 6 can be connected all in one circuit or they can be grouped in phased clusters and connected in multiple circuits. It is understood that for the ease of illustration, the PV cells 5 are shown in a straight line representing the unwrapped circular profile of the support 6.

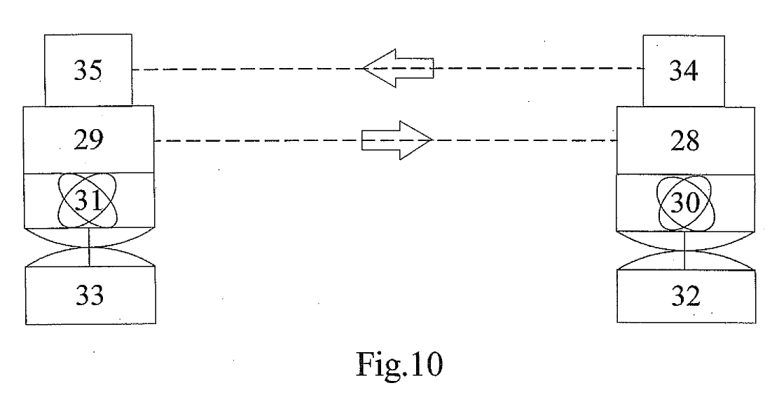

Another arrangement shown herein in FIG. 10 is the PV conversion of artificial light, addressed to a special class of applications, where the system shown uses a modular PV generator 28 which may be of the type described above in relation to the apparatus of FIG. 1 or FIG. 4 or FIG. 6 in conjunction with an IR laser 29.

Remote transmissions of data or power through laser beams from high buildings or towers may be affected by small vibrations to which the transmitter or the receiver could be subject of due to wind, nearby traffic, etc. Thus, each of them is preferably supported by a gyroscopic platform 30 and 31 respectively and optionally by a dual-axis aligning platform 32 and 33. The laser assembly is the master unit and the PV generator assembly is the slave unit. The master unit delivers the energy and initiates all the protocols for a proper functioning of the slave unit. Depending of the tasks the slave unit has to accomplish, it is equipped with a radio or laser data transmitter 34 and the master unit with the appropriate receiver 35. It is understood that the PV cells inside the module 28 are arranged to match the wavelength of the laser for achieving the best efficiency.

The slave unit can be a small robot, a radio-relay or a remote sensing device which has no other power source or uses this PV generator just as a backup. If the remote slave unit is rarely interrogated by a master data acquisition system, then for powering it a battery is not the best choice.

In some military and space applications, the slave unit could even be on the move and the optical alignment with the master unit to be maintained in a certain range of speed and change of direction.

Another embodiment associates PV generation as shown above with hybrid or remote lighting.

In hybrid lighting, a collector concentrates sunlight and filters the visible part of it using cold mirrors or other optical arrangements. Sunlight is then efficiently piped into buildings and routed into several light fixtures that combine natural and artificial light to insure a constant light output whatever the weather conditions are. This is accomplished by electronically sensing sunlight intensity and dimming the fluorescent bulbs accordingly. The main drawback of this technology is the limited number of optical fibers that can populate the focus of the collector, i.e. the limited number of light fixtures fed by a collector. For increasing the number of light fixtures, the only possibility is to use several collectors which make the technology unaffordable for most users.

The solution brought by the present arrangement is to multiply by hundreds the number of lighting fixtures using light originated from a single collector. Sunlight concentrated by the collector is first directed to an optical distributor essentially comprising the spinning mirror 3 driven by the electric motor 4 in which all or part of the PV cells 5 are replaced with heads of optical fibers that are feeding lighting fixtures. Each lighting fixture will illuminate the designated area not with a continuous flux of light but with a flickering one. If the frequency of turning light on and off is over 50 Hz, then, to the human eye, it will appear a continuous one, exactly like that emitted by a fluorescent bulb. However, the duty cycle of turning on and off the light transported by each optical fiber is not 50%. During one revolution, each fiber is “seeing” a short light pulse. Consequently, the perception of light will be more intense if the frequency of the pulses will be higher, this way avoiding flickering too. While each lighting fixture may be fed with light from a single fiber at a single location on the reception cylinder, in order to increase the amount of light and reduce the frequency, two or more optical fibers can be used at equal angular spacing in respect to the axis of the spinning mirror, their pulsing thus being out of phase.

Remote lighting can benefit from the same concept and considerations if the illuminators or light engines are redesigned. Light originating in most cases from a HID lamp is focused on a bundle of optical fibers that distribute it to a number of lighting fixtures. If light emitted by the same source is firstly collimated and directed to a spinning mirror 3 driven by an electric motor 4, then it can be distributed to a much larger number of optical fibers feeding lighting fixtures.

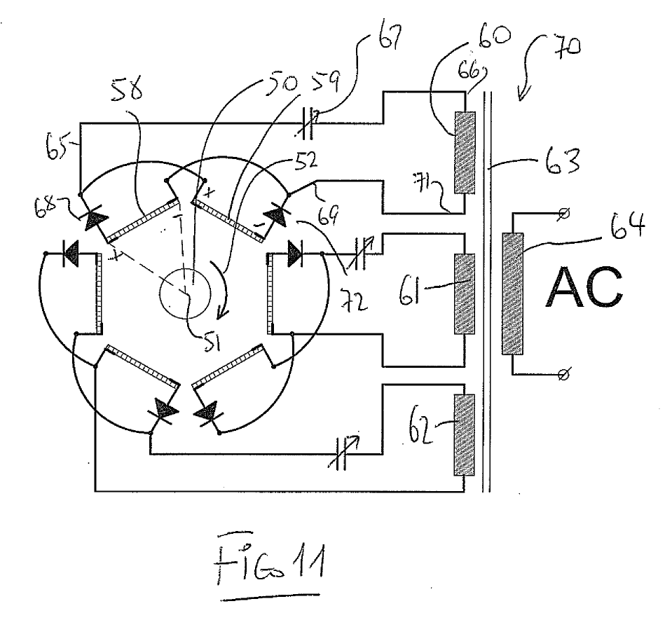

In FIG. 11 is shown an arrangement similar to that of FIG. 9A above where the redirecting member for moving the light is indicated at 50 as mounted for rotation about an axis 51 with the rotation being in a single direction as indicated by the arrow 52. There are six cells in this arrangement arranged hexagonally around the axis 51 with the edges of each cell closely adjacent so that the light scans from each cell to the next and returns at a later time to the cell.

It will be appreciated that the movement of the beam across the cell generates an output from the cell which is approximately sinusoidal in that it provides one-half of a sine wave from a minimum as the beam commences to enter onto the surface of the cell to a maximum when the beam is fully covered and finally to a minimum as the light beam moves away from the opposite edge of the cell.

Typical cells of this type are often of the order of 1.0 cms square. However in the present arrangement cells of a significantly greater size for example 4 cms along each side of the square shape can be manufactured to provide a significant increased current supply by the photovoltaic effect.

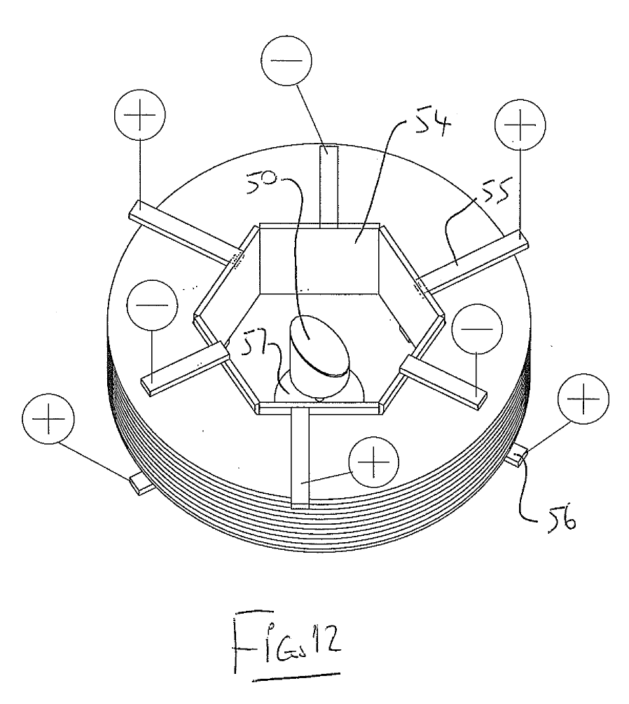

The arrangement is shown in more detail in FIG. 12 where each cell 54 is connected at its top edge to a first conductor 55 and its bottom edge to a second conductor 56. The front of each cell 54 is connected to the negative lead and the back is connected to the positive lead. To differentiate them in the drawing, the positive lead is longer than the negative one. Cells 54 are multi-junction solar cells that are illuminated with concentrated light and have a conversion efficiency over 40%.

As shown in FIG. 12, the cells are arranged so that the connecting leads of a next adjacent cell are inverted relative to a cell to form opposing pairs. The mirror 50 is located in the center of the array and mounted on a drive motor 57.

As shown in FIG. 11, the cells are arranged in pairs so that two cells 58 and 59 form a pair and are connected to a primary winding 60 of a transformer 70. Two further pairs are formed and are connected to further primary windings 61 and 62 which are connected through a core 63 to a secondary winding 64 of the transformer 70.

The positive lead of cell 58 is connected through the blocking diode 68 to the negative lead of cell 59 and to capacitor 67. The positive lead of cell 59 is connected through the blocking diode 72 to the negative lead of cell 58 and to the primary coil 60 of transformer 70. The opposite end of primary coil 60 is connected to the other end of capacitor 67. The pair of cells 58 and 59, together with capacitor 59 and primary coil 60 close a resonant circuit. The frequency of resonance can be adjusted in three ways: by varying the spinning mirror speed, or by varying the capacitance of capacitor 59, or by varying the inductance of primary coil 60 or by any combination of them. The inductance of the primary coil 60 can be adjusted in steps if it is segmented and a switching device connects to the resonant circuit a variable number of turns or if the saturation of the core 63 of transformer 70 is modified by an additional DC coil (not shown). All these techniques are well known by those skilled in the art and any combination is in the spirit of this invention.

As the light beam scans over the pair of cells 58 and 59, a half-sine wave pulse is generated by each cell as the beam passes over that cell. These pulses are created sequentially, assembled in a full cycle sine wave and applied across the primary coil 60. The blocking diodes protects the cells that are not illuminated against reverse voltage as they are sensitive to it.

In this arrangement the light does not return to the pair 58, 59 until a later time after it has passed over the further two pairs in the hexagonal array. Thus the current output from these pairs is applied to the primary coils 61 and 62 thus forming a continuous row of pulses in the core 63.

These pulses are communicated to the secondary coil for winding 64 as an output from the transformer. The voltage can be transformed to the required voltage by the selection of the primary and secondary windings.

The construction of the metallic core of the transformer acts to remove any distortion of the pulses from the cells which distortion is different from a true sine wave. Thus the effect of the core is that the output at the secondary winding 64 is substantially a true sinusoidal waveform even though there is slight distortion of the waveforms entering the primary coils 60, 61 and 62. This distortion is due to the fact that the passage of the beam over the cell does not generate a true sine wave but instead is slightly different from a sine wave and has characteristics of a Gaussian curve.

Each of the circuits from the pair of cells contains a capacitor 67. The values of the frequency relative to the inductance of the circuit and the capacitance of the circuit are selected so as to form for each of the circuits a resonant circuit which is resonant at the frequency of rotation of the light redirecting member. The capacitor 67 is indicated as being adjustable in order that the tuning of the resonance can be effected accurately at the required frequency.

This tuning of the resonance to the frequency of the pulses generated ensures that the maximum current is generated for the particular light intensity even though the light intensity may vary over a wide range. It will be appreciated that arrangements of this type can be used for generating electricity from natural sunlight which varies in intensity during the day. It is necessary therefore to control the system so that the maximum efficiency of electricity output is maintained at all time even though the light intensity will vary and therefore the characteristics of the cell will vary due to this change in light intensity.

It has been found that the maximum efficiency is obtained during these variations in light intensity substantially by the use of the tuned resonant circuit.

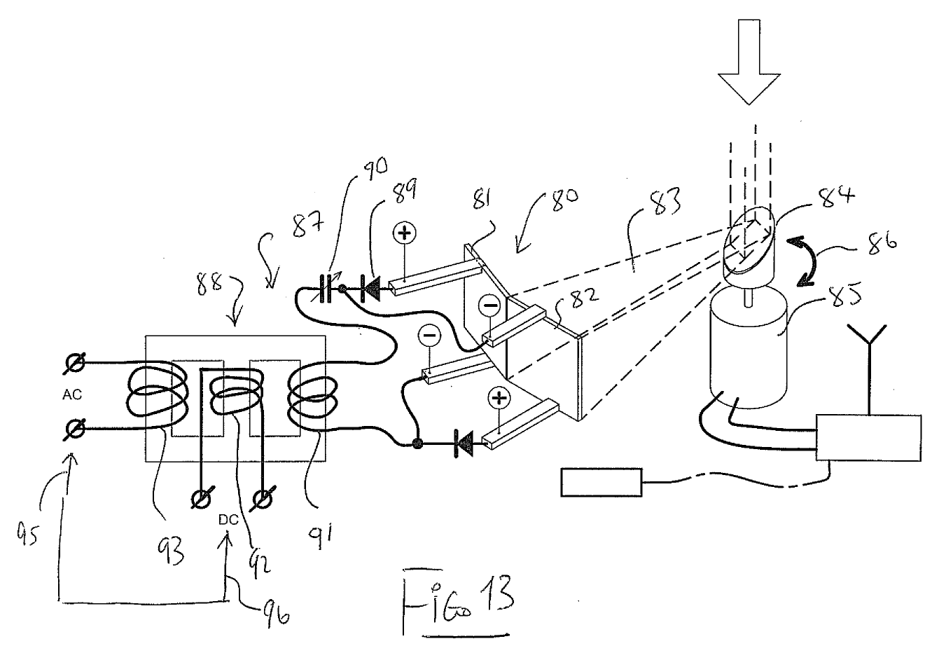

Turning now to FIG. 13, there is shown an alternative arrangement that is a single pair of cells indicated at 80. The pair includes individual cells 81 and 82 which are arranged to receive a beam of light 83 from a redirecting member 84 driven by a motor 85. However in this arrangement there is only a single pair and these are arranged such that the beam reciprocates back and forth between the pairs. Thus the motor 85 instead of being driven in a single direction in its rotational movement is driven in a reciprocating manner as indicated at 86. The beam thus moves from the cell 82 onto the cell 81 and then reverses in direction so that it moves back to the cell 82. This movement again generates approximately the sinusoidal wave pulses which are communicated through a circuit generally indicated at 87 to a transformer 88. The circuit again includes blocking diodes 89 and a variable capacitor 90 so that the circuit is tuned as previously described. In this arrangement the transformer 88 is of a type known as a magnetic amplifier which includes three windings 91, 92 and 93 so that there is an intermediate winding 92 between the primary and secondary. The intermediate 92 is connected to a DC bias. The DC bias can be operated to maintain a required output voltage across the secondary winding 93 despite changes in light intensity and thus current output from the cells. A voltage detection schematically indicated at 95 therefore can be used to control the DC bias as schematically indicated at 96.

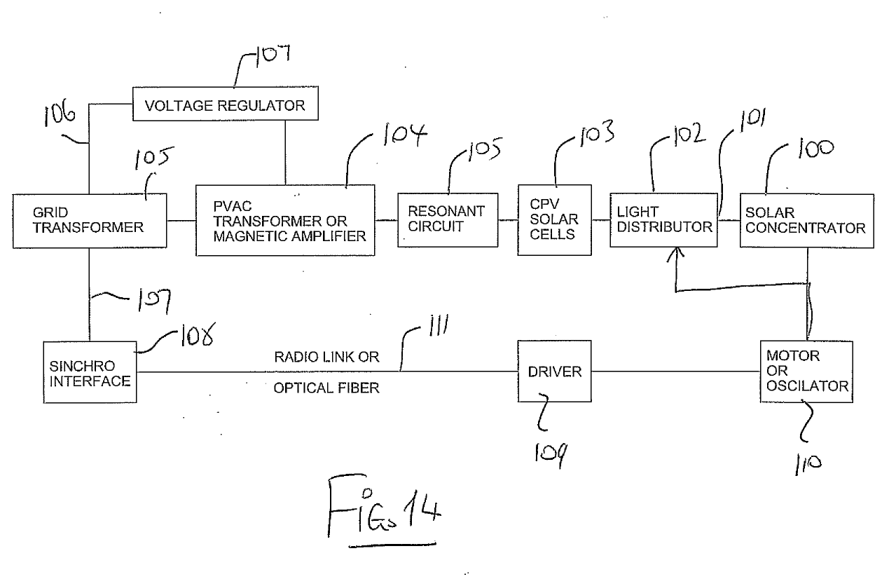

Turning now to FIG. 14, there is shown a block diagram for the production of AC from the solar cells.

As previously described, the arrangement of FIG. 14 can include a single pair of cells or can include more than one pair of cells. The movement of the beam from one cell to another can be generated by a continuous rotation in the single direction or by rotation which reciprocates.

The system shown in FIG. 14 includes the solar concentrator 100 which is a conventional device commercially available to concentrate light from the sun including commonly sun tracking systems which move the array of solar concentrators to maintain maximum light input. The solar concentrator transmits the extracted light to the input 101 of the light distributor 102. The light distributor transfers the light to the PV cells 103 using either the rotation in a single direction or the reciprocation action as previously described

The output from the PV cells is transmitted to the transformer or magnetic amplifier 104 through the resonant circuit 105. In this embodiment the output from the transformer is intended to be connected to the electricity grid as indicated by the grid transformer 105.

The grid transformer 105 is therefore connected to the electricity supply grid and can receive therefrom information concerning the required voltage and the required frequency and phase. The voltage information is communicated on a line 106 to a voltage regulator 107 which controls the transformer or the magnetic amplifier to control the output voltage therefrom which is transmitted to the grid transformer. These arrangements are previously described but can include switching arrangements which added to the system more or less turns in the transformer coils so that the voltage is maintained as the light intensity decreases. The voltage regulator therefore can include a switching system, not shown in FIG. 14.

The frequency and phase information is communicated along the line 107 which is connected to a synchronization interface 108 which supplies that information to a driver 109 controlling the motor or oscillator drive for the light distributor 102 as indicated at 110. The link between the interface 108 and the driver 109 is indicated at 111 and can be provided either by a radio link or optical fiber communicating over significant distances as required. It will be appreciated that the synchronization information from the synchronization interface 108 is connected to a significant number of light distributors in an industrial scale photovoltaic system at the speed of light, leaving no space for errors or phase shifts. A generator like that described in FIGS. 11, 12 and 14 is intended to be scaled up to 5-6 KW, in order to offer an alternative to the existing systems using inverters.

The system therefore provides a technique for directly controlling the voltage output from the cells as an AC electric supply without the necessity for the use of inverters and the control equipment associated with such inverters for controlling the output from what is generally a DC supply system. In the present invention, therefore, the output is directly an AC supply. The avoidance of DC current at any location within the system avoids the necessity for use of DC power cables which, as is well known, are significantly heavier in order to accommodate the amount of power in a DC format. All power wiring in the system of the present invention is therefore carried out in the AC cables with significant savings in copper accordingly.

A direct AC photovoltaic generator as shown in FIG. 13 cannot be scaled up too high as the mechanical inertia of the spinning mirror and associated moving parts is limiting the frequency of operation. However, it can be a cheap and viable solution for generators up to a few hundreds of watts. Along with improving the technology of making optical fibers capable to carry huge amounts of photonic power with minimum losses, the present invention is not limited to solar power but can be applied to photovoltaic conversion starting from lasers and other sources of artificial light.

Since various modifications can be made in my invention as herein above described, and many apparently widely different embodiments of same made within the spirit and scope of the claims without department from such spirit and scope, it is intended that all matter contained in the accompanying specification shall be interpreted as illustrative only and not in a limiting sense.

1. Apparatus for generating an AC electric power supply comprising:
a receiver of light from a source;
a plurality of photovoltaic cells each for receiving light from the receiver;
the photovoltaic cells being arranged in an array;
the receiver being arranged to direct the light in a beam along an axis;
a light redirecting member arranged on the axis and arranged to redirect the light in the beam away from the axis;
and a drive arrangement for causing a movement of the light redirecting member around the axis;
the array being arranged such that the beam traverses relative to the photovoltaic cells of the array so as to fall on a first one of the cells and to move from the first one of the cells to fall on a second one of the cells and subsequently to return to fall on the first one of the cells so as to fall repeatedly on each of the first and second cells as the drive arrangement causes said movement of the member;
wherein the first and second photovoltaic cells are connected to a primary winding of a transformer for delivering from the transformer the AC power supply substantially in a sinusoidal waveform.

2. The apparatus according to claim 1 wherein a frequency of the AC power supply is controlled by controlling the rate of the movement of the light redirecting member.

3. The apparatus according to claim 1 wherein the light redirecting member is arranged to direct the light into a radial plane of the axis.

4. The apparatus according to claim 1 wherein the movement of the light redirecting member is continuous in one direction.

5. The apparatus according to claim 1 wherein the cells and the transformer are arranged such that the movement of the beam on the cells together with the supply of the output of the cells to the transformer acts to generate a true sinusoidal waveform.

6. The apparatus according to claim 1 wherein there is a plurality of pairs of cells in the array with the movement arranged so as to cause the beam to fall repeatedly on each of the first and second cells of each pair as the drive arrangement causes said movement of the member.

7. Apparatus for generating an AC electric power supply comprising:
a receiver of light from a source;
a pair of photovoltaic cells each for receiving light from the receiver;
a light redirecting member arranged to redirect the light in the beam;
and a drive arrangement for causing a movement of the light redirecting member,
the cells and the light redirecting member being arranged such that the beam reciprocates back and forth relative to the pair of photovoltaic cells so as to fall on a first cell and to move in a first direction from the first cell to fall on a second cell and subsequently to move in a second opposite direction to return from the second cell to fall on the first cell;
wherein the first and second photovoltaic cells are connected to a primary winding of a transformer for delivering from the transformer the AC power supply substantially in a sinusoidal waveform.

8. The apparatus according to claim 7 wherein there are only two cells and the beam is reciprocated back and forth between the two cells.

9. The apparatus according to claim 7 wherein the light is directed along an axis and the light redirecting member reciprocates about the axis.

10. The apparatus according to claim 7 wherein a frequency of the AC power supply is controlled by controlling the rate of the movement of the light redirecting member.

11. The apparatus according to claim 7 wherein the cells and the transformer are arranged such that the movement of the beam on the cells together with the supply of the output of the cells to the transformer acts to generate a true sinusoidal waveform.

12. The apparatus according to claim 7 wherein the cells and the transformer are connected in a circuit with a capacitor such that the inductance and the capacitance of the circuit are selected relative to a frequency of the movement such that the circuit is resonant at the frequency.

13. The apparatus according to claim 7 wherein the transformer is controlled so as to generate a required output voltage in the AC power supply while accommodating changes in light intensity in the beam.

14. The apparatus according to claim 13 wherein the transformer comprises a magnetic amplifier.

15. The apparatus according to claim 14 wherein the magnetic amplifier includes a DC biasing coil between the primary coil and the output secondary coil.

16. The apparatus according to claim 13 wherein the transformer is controlled by a voltage regulator which includes switch systems for adding and subtracting pairs of cells as light intensity decreases and increases.

17. The apparatus according to claim 7 wherein the transformer is connected to a grid transformer to connect the AC power supply to an electricity grid and wherein there is provided a link for synchronizing the frequency and phase of the grid to the frequency and phase of the drive arrangement.

18. The apparatus according to claim 17 wherein the link includes a radio connection.

19. The apparatus according to claim 17 wherein the link includes an optical fiber.

20. Apparatus for generating an AC electric power supply comprising:
a receiver of light from a source;
a plurality of photovoltaic cells each for receiving light from the receiver;
a light redirecting member arranged to redirect the light in the beam;
and a drive arrangement for causing a movement of the light redirecting member;
the cells and the light redirecting member being arranged such that the beam scans over the photovoltaic cells so as to fall repeatedly on each cell and to move from that cell to another cell;
wherein at least two of the cells are connected to a primary winding of a transformer for delivering from the transformer the AC power supply substantially in a sinusoidal waveform;
and wherein the cells and the transformer are connected in a circuit with a capacitor such that the inductance and the capacitance of the circuit are selected relative to a frequency of the movement such that the circuit is resonant at the frequency.

21. The apparatus according to claim 20 wherein the light is directed along an axis and the light redirecting member moves about the axis.

22. The apparatus according to claim 20 wherein the cells and the transformer are arranged such that the movement of the beam on the cells together with the supply of the output of the cells to the transformer acts to generate a true sinusoidal waveform.

23. The apparatus according to claim 20 wherein the transformer is controlled so as to generate a required output voltage in the AC power supply while accommodating changes in light intensity in the beam.

24. The apparatus according to claim 23 wherein the transformer comprises a magnetic amplifier.

25. The apparatus according to claim 24 wherein the magnetic amplifier includes a DC biasing coil between the primary coil and the output secondary coil.

26. The apparatus according to claim 23 wherein the transformer is controlled by a voltage regulator which includes switch systems for adding and subtracting pairs of cells as light intensity decreases and increases.

27. The apparatus according to claim 20 wherein the transformer is connected to a grid transformer to connect the AC power supply to an electricity grid and wherein there is provided a link for synchronizing the frequency and phase of the grid to the frequency and phase of the drive arrangement.

28. Apparatus for generating an AC electric power supply comprising:
a receiver of light from a source;
a plurality of photovoltaic cells each for receiving light from the receiver;
a light redirecting member arranged to redirect the light in the beam;
and a drive arrangement for causing a movement of the light redirecting member;
the cells and the light redirecting member being arranged such that the beam scans over the photovoltaic cells so as to fall repeatedly on each cell and to move from that cell to another cell;
wherein at least two of the cells are connected to a primary winding of a transformer for delivering from the transformer the AC power supply substantially in a sinusoidal waveform;
wherein the transformer is connected to a grid transformer to connect the AC power supply to an electricity grid and wherein there is provided a link for synchronizing the frequency and phase of the grid to the frequency and phase of the drive arrangement.

29. The apparatus according to claim 28 wherein the link includes a radio connection.

30. The apparatus according to claim 28 wherein the link includes an optical fiber.
